(19) United States
(12) Patent Application Publication
(10) Pub. No.: US 2026/0076194 A1
(43) Pub. Date: Mar. 12, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Seul Bee Lee, Incheon (KR); Jae Jin Lee, Gyeonggi-do (KR); Seung Jae Yu, Incheon (KR); Myung Jea Choi, Incheon (KR); Gi Tae Lim, Seoul (KR); Dong Joo Park, Incheon (KR); Kyung Rok Park, Incheon (KR)

(73) Assignee: Amkor Technology Singapore Holding Pte. Ltd., Singapore (SG)

(21) Appl. No.: 19/320,999

(22) Filed: Sep. 5, 2025

Related U.S. Application Data
(60) Provisional application No. 63/693,973, filed on Sep. 12, 2024.

(51) Int. Cl. H01L 23/373; H01L 21/48; H01L 21/56; H01L 23/00; H01L 23/31; H01L 23/498; H01L 23/538; H01L 25/10

(52) U.S. Cl. CPC H10W 40/258; H10W 70/023; H10W 70/093; H10W 70/611; H10W 74/014; H10W 74/117; H10W 90/00; H10W 90/401; H10W 90/701; H10W 70/60; H10W 72/0198; H10W 72/072; H10W 72/07232; H10W 72/07236; H10W 72/07254; H10W 72/241; H10W 72/247; H10W 72/265; H10W 72/267; H10W 72/877; H10W 74/15; H10W 90/288; H10W 90/722; H10W 90/724; H10W 90/734; H10W 90/754

(57) ABSTRACT

In one example, an electronic device comprises a substrate having a first conductive structure, an electronic component coupled to the first conductive structure at a first side of the substrate, wherein the electronic component includes a first side facing the first side of the substrate and a second side opposite the first side, vertical interconnects around the electronic component, wherein the vertical interconnects are coupled to the first conductive structure at the first side of the substrate, an interposer having a second conductive structure coupled to the plurality of vertical interconnects, a thermal body coupled between the electronic component and the interposer, and an encapsulant between the substrate and the interposer, around the thermal body, around the plurality of vertical interconnects, and around the electronic component. Other examples and related methods are also disclosed herein.

### CROSS REFERENCE TO RELATED APPLICATIONS

This application claims the benefit of U.S. Provisional Application No. 63/693,973 filed on Sep. 12, 2024, which is incorporated herein by reference.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting, for example in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2E show cross-sectional views of an example method for manufacturing the first example electronic device.

FIG. 3 shows a cross-sectional view of a second example electronic device coupled to the first example electronic device.

FIG. 4 shows a cross-sectional view of a third example electronic device.

FIGS. 5A to 5E show cross-section and top-down views of an example method for manufacturing the third example electronic device.

FIG. 6 shows a cross-sectional view of the second example electronic device coupled to the third example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements. The elements described using “first,” “second,” etc. are not to be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” and “on” may be used to describe two elements directly contacting each other or to describe two elements indirectly coupled by one or more other elements. Unless specified otherwise, the term “coupled” can refer to a mechanical coupling or an electrical coupling.

### DESCRIPTION

In one example, an electronic device can include a substrate having a first side, a second side opposite the first side of the substrate, and a first conductive structure, an electronic component coupled to the first conductive structure at the first side of the substrate, a plurality of vertical interconnects disposed around the electronic component, an interposer coupled to the plurality of vertical interconnects, a thermal body coupled to the electronic component and to the interposer, and an encapsulant disposed between the substrate and the interposer, around the thermal body, around the plurality of vertical interconnects, and around the electronic component. The electronic component can have a first side facing the first side of the substrate and a second side opposite the first side of the electronic component. The interposer can have a first side facing the first side of the substrate, a second side opposite the first side of the interposer, and a second conductive structure. The plurality of vertical interconnects can be coupled to the second conductive structure at the first side of the interposer. The thermal body can be coupled to the second side of the electronic component and to the first side of the interposer.

In another example, a method to manufacture an electronic device can include providing a substrate having a first side, a second side opposite the first side of the substrate, and a first conductive structure, providing an electronic component coupled to the first conductive structure at the first side of the substrate, providing a plurality of vertical interconnects disposed around the electronic component, providing an interposer coupled to the plurality of vertical interconnects, providing a thermal body coupled to the electronic component and to the interposer, and providing an encapsulant disposed between the substrate and the interposer, around the thermal body, around the plurality of vertical interconnects, and around the electronic component. The electronic component can have a first side facing the first side of the substrate and a second side opposite the first side of the electronic component. The plurality of vertical interconnects can be coupled to the first conductive structure at the first side of the substrate. The interposer can have a first side facing the first side of the substrate, a second side opposite the first side of the interposer, and a second conductive structure. The plurality of vertical interconnects can be coupled to the second conductive structure at the first side of the interposer. The thermal body can be coupled to the second side of the electronic component and to the first side of the interposer.

In yet another example, an electronic device can include a substrate having a first side, a second side opposite the first side of the substrate, and a first conductive structure, an electronic component coupled to the first conductive structure at the first side of the substrate, an interposer having an inner conductive region, a plurality of vertical interconnects disposed around the electronic component and around the inner conductive region, and an encapsulant disposed between the substrate and the interposer, around the plurality of vertical interconnects, and around the electronic component. The electronic component can have a first side facing the first side of the substrate and a second side opposite the first side of the electronic component. The interposer can have a first side facing the first side of the substrate, a second side opposite the first side of the interposer, and a second conductive structure. The inner conductive region can extend from the first side of the interposer to the second side of the interposer. The plurality of vertical interconnects can be coupled to the first conductive structure at the first side of the substrate and can be coupled to the second conductive structure at the first side of the interposer.

Other examples are included in the present disclosure. Such examples may be found in the figures, in the claims, or in the description of the present disclosure.

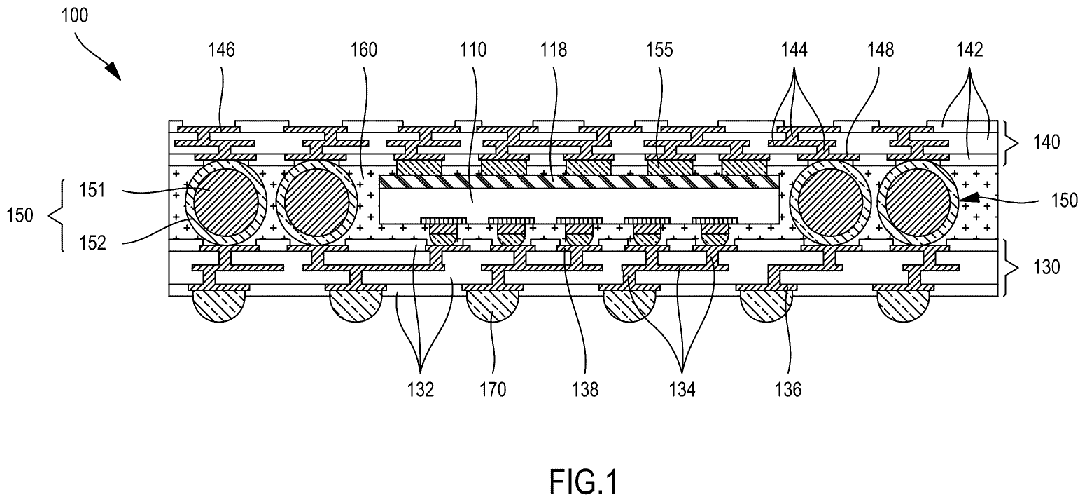

FIG. 1 shows a cross-sectional view of an electronic device 100. In the example shown in FIG. 1, electronic device 100 can comprise one or more electronic components 110, metallization layer 118, substrate 130, interposer 140, vertical interconnects 150, one or more thermal bodies 155, encapsulant 160, and external interconnects 170.

Electronic component 110, substrate 130, and interposer 140 can each comprise a proximal side and a distal side opposite the proximal side. Electronic component 110 can be coupled to substrate 130. Proximal side of electronic component 110 can be coupled to distal side of substrate 130. In some examples, electronic component 110 can comprise contacts and/or connectors along its proximal side and can be coupled to substrate 130 through the contacts and/or connectors. Proximal side of interposer 140 can be coupled to distal side of substrate 130. Proximal side of interposer 140 can face distal side of electronic component 110.

Substrate 130 can comprise dielectric structure 132 and conductive structure 134. Conductive structure 134 can comprise inner terminals 138 positioned along the distal side of substrate 130 and outer terminals 136 positioned along the proximal side of substrate 130. Electronic components 110 can be coupled to distal side and/or proximal side of substrate 130, for example via the inner terminals 138 and/or outer terminals 136, respectively.

Interposer 140 can comprise dielectric structure 142 and conductive structure 144. Conductive structure 144 can comprise inner terminals 148 positioned along the proximal side of interposer 140 and outer terminals 146 positioned along the distal side of interposer 140. Interposer 140 can comprise a plurality of outer sidewalls facing the exterior of the interposer 140. In some examples, interposer 140 can comprise or be referred to as a substrate. Electronic components can be coupled to distal side and/or proximal side of interposer 140, for example via the outer terminals 146 and/or inner terminals 148.

Vertical interconnects 150 can comprise conductive pathways and/or structural support between substrate 130 and interposer 140. In some examples, vertical interconnects 150 can couple distal side of substrate 130 to proximal side of interposer 140, for example coupling inner terminals 138 of substrate 130 to inner terminals 148 of interposer 140. External interconnects 170 can be coupled to outer terminals 136 of substrate 130, and can provide electrical pathways for electronic component(s) 110, vertical interconnects 150, interposer 140, other devices coupled to interposer 140, and/or other features of electronic device 100, to couple with an external device, system, or the like.

In various examples, vertical interconnects 150 can comprise metallic core balls, metallic pins, metallic pillars, or other conductive structures. Some examples can include vertical interconnects 150 comprising multiple stacked metallic core balls, metallic pins, metallic pillar, other conductive structures, and/or combination thereof. Vertical interconnects 150 can comprise a core structure 151 comprising a metal (e.g., copper or other metal) or alloy inner core with a fusible material 152 or other flowable material disposed around core structure 151. Core structure 151 can be coupled to substrate 130 and/or interposer 140 by fusible material 152. Substrate 130 can be electrically coupled to interposer 140 through vertical interconnects 150. In some examples, the height of vertical interconnects 150 can be greater than or equal to the heigh of electronic component 110 coupled to substrate 130.

Thermal bodies 155 can be coupled to electronic component 110. In some examples, a proximal side of thermal bodies 155 can be coupled to the distal side of electronic component 110, and a distal side of thermal bodies 155 can be coupled to the proximal side of interposer 140. A thermal body 155 can function as a thermal pathway for removal of thermal energy from electronic device 100. Thermal bodies 155 can be referred to and can comprise thermally conductive spacers, a conductive paste, solder bumps, pillars, other solder structures, other metal structures, or other thermally conductive material.

Metallization layer 118 can be between distal side of electronic component 110 and thermal bodies 155. In some examples, a metallization layer 118 can be disposed on distal side of electronic component 110, and thermal bodies 155 can be coupled to electronic component 110 through metallization layer 118. Metallization layer 118 can be referred to as or comprise a backside metallization layer. Metallization layer 118 can provide enhanced wetting with thermal bodies 155 and can comprise a metal such as gold (Au), silver (Ag), or a similar material. Metallization layer 118, thermal bodies 155, and interposer 140 can form a thermal pathway for heat produced by electronic component 110, for example transferring thermal energy from electronic component 110 to an exterior of electronic device 100. Metallization layer 118, thermal bodies 155, and/or interposer 140 can facilitate removal of thermal energy through interposer 140, through an exterior edge of electronic device 100, or the like.

Encapsulant 160 can be disposed in and/or around the various features of electronic device 100. In some examples, encapsulant 160 can be disposed in and/or around thermal bodies 155, around vertical interconnects 150, around electronic component 110, between electronic component 110 and substrate 130, between electronic component 110 and interposer 140, between substrate 130 and interposer 140, and/or the like. In some examples, encapsulant 160 can extend to the exterior edges of electronic device 100, and can be coplanar with one or more lateral sides of substrate 130 and/or interposer 140. In some examples, outer sidewalls of interposer 140 can be recessed from the lateral sides of substrate 130 and the exterior sides of encapsulant 160, and encapsulant 160 can be located between outer sidewalls of interposer 140 and edges of electronic device 100.

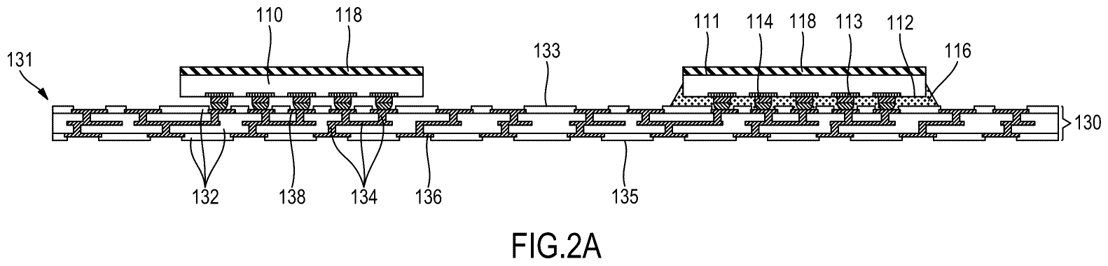

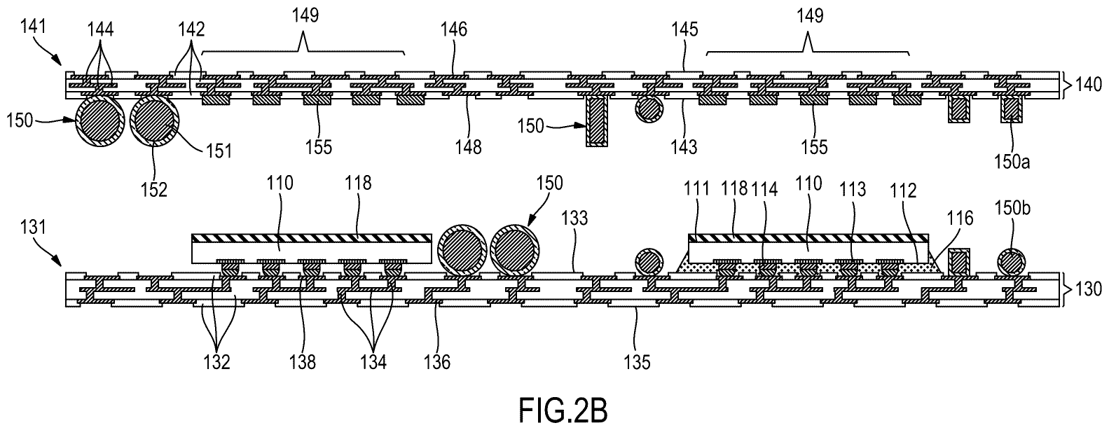

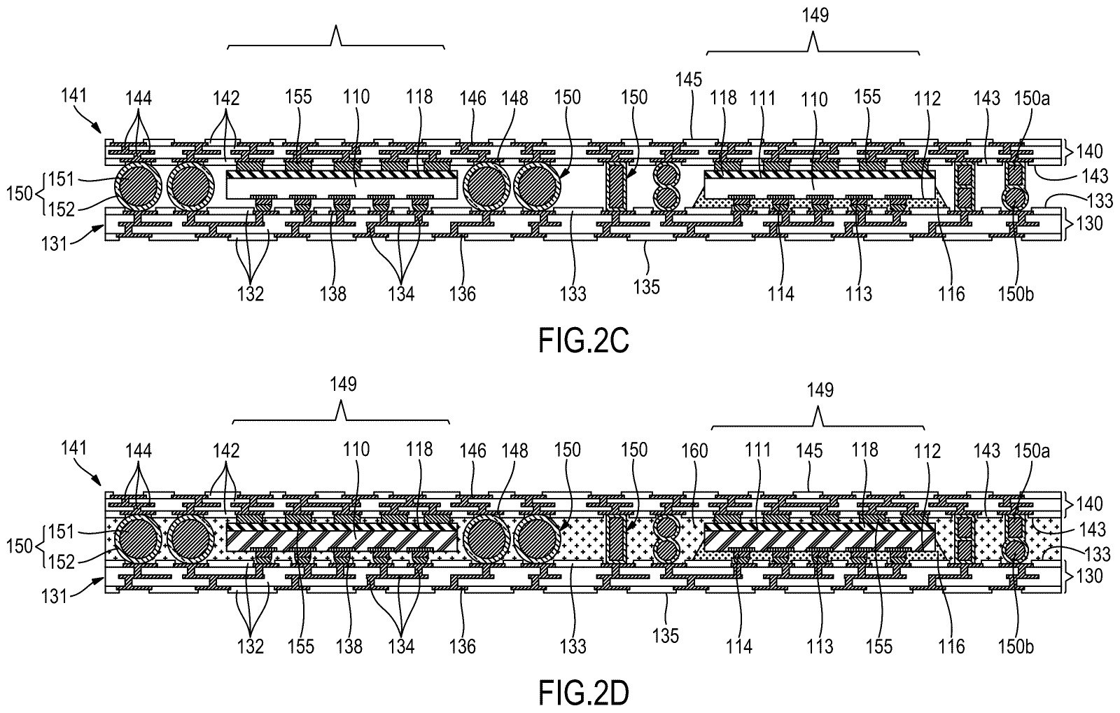

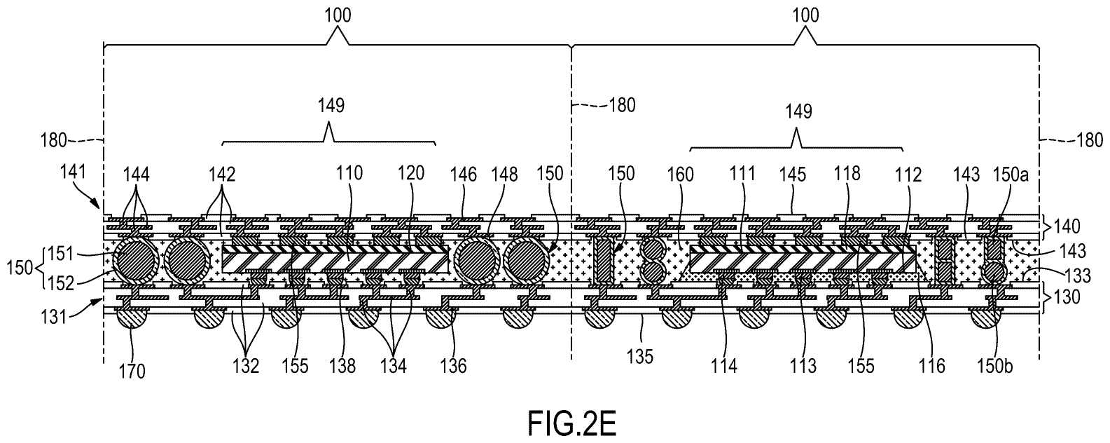

FIGS. 2A to 2F show cross-sectional views of an example method for manufacturing an example electronic device, such as electronic device 100 shown and described with respect to FIG. 1. FIG. 2A shows a cross-sectional view of electronic device 100 at an early stage of manufacture. In the example shown in FIG. 2A, substrate 130 is provided and electronic components 110 are provided over substrate 130.

In some embodiments, substrate 130 can be provided as part of a strip 131 of substrates 130. Substrate strip 131 can include multiple adjacent, connected substrates 130. In some embodiments, substrate 130 can be provided as one or more separate individual substrates, for example coupled to a carrier. Substrate 130 includes proximal side 135 and distal side 133, with proximal side 135 opposite (e.g., oriented away from) distal side 133.

In accordance with various examples, substrate 130 can comprise dielectric structure 132 and conductive structure 134. In some examples, dielectric structure 132 can comprise or be referred to as one or more stacked dielectric layers. For instance, the one or more dielectric layers can comprise one or more core layers, polymer layers, pre-preg layers, solder mask layers, or the like stacked on each other. One or more layers or elements of conductive structure 134 can be interleaved with elements or layers of dielectric structure 132. In some examples, dielectric structure 132 can comprise polymer, bismaleimide triazine (BT), polyimide (PI), benzocyclobutene (BCB), polybenzoxazole (PBO), Ajinomoto Buildup Film (ABF), resin, mold compound, ceramic, glass, silicon, copper clad laminate, or flame retardant material (e.g., FR4 comprising laminated layers of copper foil and glass fiber fabric). Dielectric structure 132 can maintain the shape of substrate 130 and can structurally support conductive structure 134. In some examples, the thickness of dielectric structure 132 can range from approximately 2 μm (micrometers) to approximately 200 μm, for example from approximately 5 μm to approximately 100 μm, for example from approximately 10 μm to approximately 50 μm or approximately 10 μm to approximately 35 μm, or approximately 2 μm to approximately 10 μm. The thickness of dielectric structure 132 can refer to individual layers of dielectric structure 132. The overall thickness of dielectric structure 132 can provide or be generally equal to the thickness of substrate 130.

Conductive structure 134 can comprise or be referred to as one or more conductive layers defining signal distribution elements, traces, vias, pads, conductive patterns, conductive paths, wiring patterns, circuit patterns, or under bump metallization (UBM). In some examples, conductive structure 134 can comprise one or more layers of copper (Cu), aluminum (Al), tin (Sn), titanium (Ti), titanium tungsten (TiW), gold (Au), silver (Ag), nickel (Ni), palladium (Pd), combinations or alloys thereof, or the like. The layers and elements of conductive structure 134 can be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or any other suitable metal deposition process. The thickness of conductive structure 134 can range from approximately 1 μm to approximately 50 μm, for example from approximately 2 μm to approximately 20 μm, for example from approximately 2 μm to approximately 10 μm. The thickness of conductive structure 134 can refer to individual layers of conductive structure 134. Conductive structure 134 can provide electrical signal paths (e.g., vertical paths and horizontal paths) through dielectric structure 132. Conductive structure 134 can, for example, couple external connections to one or more electronic components 110. In some examples, conductive structure 134 can provide electrical signal paths between one or more electronic components 110. In some examples, conductive structure 134 can provide electrical signal paths to other features of electronic device 100, such as interposer 140, vertical interconnects 150, or the like.

Conductive structure 134 can be exposed at distal side 133 of substrate 130 and can comprise inner terminals 138 along distal side 133 of substrate 130. Conductive structure 134 can be exposed at proximal side 135 of substrate 130 and can comprise outer terminals 136 along proximal side 135 of substrate 130. In some examples, inner terminals 138 and outer terminals 136 can comprise or be referred to as pads, lands, studs, or UBM. Layers and elements of conductive structure 134 can electrically couple inner terminals 138 with outer terminals 136.

In some examples, substrate 130 can be a pre-formed substrate. Pre-formed substrates can be manufactured prior to attachment to an electronic device and can comprise dielectric layers between respective conductive layers, for example layers of dielectric structure 132 between layers of conductive structure 134. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. In examples where the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4. In some examples, the core can comprise glass. The dielectric and conductive layers can be provided on the permanent core structure. In other examples, the pre-formed substrate can be a coreless substrate omitting the permanent core structure, and the dielectric and conductive layers can be provided on a sacrificial carrier that is removed after formation of the dielectric and conductive layers and before attachment to the electronic device. The pre-formed substrate can be referred to as a printed circuit board (PCB) or a laminate substrate. Such pre-formed substrates can be formed through a semi-additive or modified-semi-additive process.

In some examples, substrate 130 can be a redistribution layer (“RDL”) substrate. RDL substrates can comprise one or more conductive redistribution layers, for example conductive structure 134, and one or more dielectric layers, for example dielectric structure 132, that (a) can be formed layer by layer over an electronic device to which the RDL substrate is to be coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly formed with one or more conductive layers that define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal.

The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film.

To permit proper formation of desired photo-defined features, such photo-definable dielectric materials can omit structural reinforcers or can be filler-free, without strands, weaves, or other particles, which could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layers can comprise silicon nitride (Si3N4), silicon oxide (SiO2), or silicon oxynitride (SiON). The inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. RDL substrates can omit the permanent core or carrier structure generally associated with preformed, laminate substrates. The minimum trace width and trace spacing of RDL substrates can be less than the minimum trace width and trace spacing associated with pre-formed substrates. RDL substrates can provide a greater trace density and/or smaller pitch, as compared to preformed substrates.

In accordance with various embodiments, one or more electronic component(s) 110 can be provided on distal side 133 of substrate 130. Electronic component(s) 110 can be coupled to conductive structure 134 of substrate 130. For example, electronic components 110 can be coupled to inner terminals 138. Electronic components 110 can comprise proximal side 112 facing distal side 133 of substrate 130 and distal side 111 opposite proximal side 112. In some examples, proximal side 112 can comprise or be referred to as an active side of electronic components 110. Electronic components 110 can include contacts 113 on the active side of the electronic components 110. Contacts 113 can comprise or be referred to as contact pads or bond pads, in some examples. In some examples, contacts 113 can comprise a metal exposed via an inorganic dielectric material such as silicon dioxide (SiO₂) or silicon nitride (Si3N4) located over the active side of electronic components 110. For example, contacts 113 can be the final metal layer formed at the back-end-of-line (BEOL) stage. In some examples, contacts 113 can be exposed via an organic dielectric material or a solder resist material formed over the BEOL layers.

In some examples, connectors 114 can couple electronic components 110 to substrate 130. Connectors 114 can couple contacts 113 of electronic components 110 to substrate inner terminals 138. Connectors 114 can comprise or be referred to as bumps, tin-lead (SnPb) bumps, lead-free bumps, copper pillars, stud bumps, pillars, posts, solder capped metal pillars, etc.

In accordance with various examples, electronic component 110 can comprise or be referred to as a die, chip, semiconductor package (e.g., multiple interconnected and/or stacked die), passive component, antenna patch, or power device. In some examples, electronic component 110 can comprise a digital signal processor (DSP), network processor, power management unit, audio processor, radio-frequency (RF) circuit, wireless baseband processor, system-on-chip (SoC) processor, sensor, or application-specific integrated circuit (ASIC). In some examples, electronic component 110 can be configured to perform calculation and control processing, store data, or remove noise from electrical signals.

In some examples, pick-and-place equipment can pick up electronic components 110 and place electronic components 110 on distal side 133 of substrate 130. Connectors 114 can be positioned on top of inner terminals 138 of substrate 130 or on contacts 113 of electronic component 110. Subsequently, contacts 113 of electronic component 110 can be coupled to inner terminals 138 by means of bonding connectors 114 to contacts 113 or inner terminals 138 using, for example, a reflow, thermal-compression, or laser assisted bonding process. While electronic components 110 are shown in flip-chip configuration with contacts 113 oriented toward substrate 130, there can be examples where one or more electronic components 110 are oriented in a face-up or wire-bond configuration with contacts 113 oriented away from substrate 130 and connectors 114 comprising wire bonds, for example.

In some examples, underfill 116 can be disposed between electronic component 110 and substrate 130, before or after placement and/or coupling of electronic component 110 on substrate 130. Underfill 116 can include a liquid molding compound (LMC), a capillary underfill (CUF), a molded underfill (MUF), a nonconductive paste (NCP), or the like. In some examples, underfill 116 can be applied to electronic component 110 by dispensing or printing.

In some examples, the thickness of electronic component 110 can range from about 50 μm to about 400 μm. In some examples, the area of each of electronic components 110 can range from about 0.5 mm (millimeter)×0.5 mm to about 10 mm×10 mm. The scope of the disclosed subject matter is not limited in these respects.

In some examples, metallization layer 118 can be provided on distal side 111 of electronic components 110. In various embodiments, one or more portions of distal side 111 or the entire upper surface of distal side 111 can be covered by metallization layer 118. In some examples, distal side 111 of electronic components 110 can directly contact metallization layer 118.

Metallization layer 118 can comprise one or more metal layers. In some examples, metallization layer 118 can comprise gold (Au). In some examples, metallization layer 118 can comprise a multi-layer metal stack. For example, metallization layer 118 can comprise an adhesion layer (e.g., Ti, TiW, Cr) applied on distal side 111, a barrier layer (e.g., Ni or NiV) applied on the adhesion layer, and a wetting layer (e.g., Au or Ag) applied on barrier layer. In some examples, the thickness of layer 114 can range from approximately 0.3 μm to approximately 10 μm.

In some examples, metallization layer 118 can comprise or be referred to as a backside metallization. Metallization layer 118 can have a substantially uniform thickness. In some examples, metallization layer 118 can be provided with a substantially uniform thickness through sputtering or plating. For example, metallization layer 118 can be provided by electrolytic plating, electroless plating, sputtering, PVD, CVD, MOCVD, ALD, LPCVD, PECVD, or any other suitable metal deposition process. In some examples, metallization layer 118 can have a thickness of 0.1 micrometers (μm) to 1000 μm, for example from 10 μm to 500 μm, for example from 50 μm to 200 μm, 1.0 μm to 20 μm, or 0.3 μm to 10 μm.

FIG. 2B shows a cross-sectional view of electronic device 100 at a later stage of manufacture. In the example shown in FIG. 2B, vertical interconnects 150 and interposer 140 can be provided over substrate 130. In some examples, vertical interconnects 150 can be coupled to interposer 140 and then interposer 140, having vertical interconnects 150 coupled thereto, is disposed over substrate 130. In some examples, vertical interconnects 150 can be coupled to substrate 130, and then interposer 140 can be disposed over vertical interconnects 150 and substrate 130. In some examples, vertical interconnects 150 can comprise multiple interconnect segments 150a, 150b. In some such examples, a proximal interconnect segment 150b can be coupled to substrate 130 and a distal interconnect segment 150a can be coupled to interposer 140. Interposer 140 can then be disposed over substrate 130 such that the proximal interconnect segment 150b can couple with the distal interconnect segment 150a.

In some embodiments, interposer 140 can be provided as part of a strip 141 of interposers 140. Interposer strip 141 can include multiple adjacent, connected interposers 140. In some embodiments, interposer 140 can be provided as one or more separate individual interposers. Interposer 140 can include proximal side 143 and distal side 145 opposite proximal side 143. In some examples, pick-and-place equipment can pick up interposer 140 and align vertical interconnects 150, 150a, 150b on inner terminals 138 of substrate 130 and/or inner terminals 148 of interposer 140. Proximal side 143 of interposer 140 can be oriented toward, for example facing, distal side 133 of substrate 130.

In accordance with various embodiments, interposer 140 can comprise dielectric structure 142 and conductive structure 144. In some examples, dielectric structure 142 can comprise or be referred to as one or more stacked dielectric layers. For instance, the one or more dielectric layers can comprise one or more core layers, polymer layers, pre-preg layers, solder mask layers, or the like stacked on each other. One or more layers or elements of conductive structure 144 can be interleaved with elements or layers of dielectric structure 142. In some examples, dielectric structure 142 can comprise FR4, BT, PI, BCB, PBO, ABF, resin, mold compound, ceramic, glass, silicon, or copper clad laminate. The thickness of individual layers of dielectric structure 142 can range from approximately 2 μm to approximately 200 μm, for example from approximately 5 μm to approximately 100 μm, for example from approximately 10 μm to approximately 50 μm or approximately 10 μm to approximately 35 μm, or approximately 2 μm to approximately 10 μm. The combined thickness of the layers of dielectric structure 142 can define the thickness of interposer 140. Dielectric structure 142 can maintain the shape of interposer 140 and can structurally support conductive structure 144.

Conductive structure 144 can comprise or be referred to as one or more conductive layers defining signal distribution elements, traces, vias, pads, conductive patterns, conductive paths, wiring patterns, circuit patterns, or UBM. In some examples, conductive structure 144 can comprise one or more layers of Cu, Al, Sn, Ti, TiW, Au, Ag, Ni, Pd, combinations or alloys thereof, or the like. The layers and elements of conductive structure 144 can be provided as described above with respect to the layers and elements of conductive structure 134. The thickness of conductive structure 144 can range from approximately 1 μm to approximately 50 μm, approximately 2 μm to approximately 20 μm, or approximately 2 μm to approximately 10 μm. The thickness of conductive structure 144 can refer to individual layers of conductive structure 144. Conductive structure 144 can provide electrical signal paths, for example vertical paths or horizontal paths, through dielectric structure 142. Conductive structure 144 can, for example, couple external connections to one or more electronic components 110. In some examples, conductive structure 144 can provide electrical signal paths between one or more electronic components 110. In some examples, conductive structure 144 can provide electrical signal paths to other features of electronic device 100, such as vertical interconnects 150, conductive structure 134 of substrate 130, or the like.

Conductive structure 144 can be exposed at proximal side 143 and/or distal side 145 of interposer 140. Conductive structure 144 can comprise inner terminals 148 provided along proximal side 143 of interposer 140, and outer terminals 146 provided along distal side 145 of interposer 140. In some examples, inner terminals 148 and outer terminals 146 can comprise or be referred to as pads, lands, or UBM. Layers and elements of conductive structure 144 can electrically couple inner terminals 148 with outer terminals 146. In some examples, elements, features, materials, or manufacturing methods of interposer 140 can be similar to or the same as those of substrate 130. In some examples, interposer 140 can comprise or be referred to as a substrate. Interposer 140 can comprise a core or be coreless. In some examples, interposer 140 can comprise or be referred to as a pre-formed or laminate substrate, as previously described. In some examples, interposer 140 can comprise or be referred to as an RDL substrate, as previously described. In examples where interposer 140 comprises an RDL substrate, interposer 140 can be disposed over substrate 130 with a support carrier coupled to distal side 145 of interposer 140.

In accordance with various embodiments, vertical interconnects 150 can be provided on proximal side 143 of interposer 140 and/or distal side 133 of substrate 130. Vertical interconnects 150 can be coupled to conductive structures 144 of interposer 140 and/or conductive structure 134 of substrate 130. For example, vertical interconnects 150 can be coupled to inner terminals 148 on proximal side 143 of interposer 140 and/or inner terminals 138 on distal side 133 of substrate 130.

In some examples, vertical interconnects 150 can comprise or be referred to as solder balls, plated pillars, pre-formed pins, copper column cubes (CCCs) (e.g., vertical interconnects 150 can include a plurality of encapsulated conductive (e.g., Cu) columns), solder coated metallic core balls (e.g., solder coated Cu core balls), solder coated metallic core pins (e.g., solder coated Cu core pins), or vertical wires. Vertical interconnects 150 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. Vertical interconnects 150 can be provided by ball drop, screen printing, electrolytic plating, or coupling a pre-formed structure on inner terminals 148 and/or inner terminals 138. In some examples, vertical interconnects 150 can comprise core structure 151 covered by fusible material 152. For example, vertical interconnects 150 can comprise solder-coated metal core balls or solder-coated metal core pins (e.g., cuboid core, cylindrical core, etc.). Examples of solder can include a flowable or eutectic material, such as a fusible metal or metal alloy formulated to join metallic surfaces by forming a metallurgical bond upon melting and subsequent solidification. Solder can include, for example, tin-based, lead-based, lead-free, or silver-based alloys, and can be applied in various forms such as wire, paste, preforms, or the like. The vertical interconnects 150 can be configured to maintain a distance between interposer 140 and substrate 130 that is greater than the height of electronic components 110. In some examples, the height of vertical interconnects 150 and/or core structure 151 or vertical interconnects 150 can be greater than the thickness of electronic components 110. For example, the height of core structure 151 of vertical interconnects 150 can range from about 70 μm to about 420 μm.

In some embodiments, interposer 140 can comprise inner conductive region 149. In some examples, inner conductive region 149 can be centrally located in interposer 140. Vertical interconnects 150 can be disposed around one or more lateral sides of inner conductive region 149. In some examples, inner conductive region 149 can be disposed above electronic device 100. Inner conductive region 149 can have dimensions larger than, equal to, or smaller than electronic component 110 in one or more lateral directions.

Inner conductive region 149 can comprise the same structures and composition as interposer 140 external to inner conductive region 149. In some examples, inner conductive region 149 can extend from proximal side 143 to distal side 145 of interposer 140. For example, inner conductive region 149 can include dielectric structure 142, conductive structure 144, outer terminals 146, and inner terminals 148. In some examples, conductive structure 144, outer terminals 146, and/or inner terminals 148 of inner conductive region 149 can be electrically isolated from conductive structure 144, outer terminals 146, and/or inner terminals 148 of interposer 140 surrounding inner conductive region 149. Conductive structure 144 of inner conductive region 149 can provide a thermal pathway for conducting heat between proximal side 143 of interposer 140 and distal side 145 of interposer 140, for example from thermal bodies 155 to an exterior of electronic device 100. In some examples, interposer 140 can include a metallization layer or metal plate (e.g., Au, Cu, alloys, etc.) coupled to proximal side 143 of interposer 140 and/or to distal side 145 of interposer 140 in inner conductive region 149, instead of or in addition to inner terminals 148 and/or outer terminals 146, respectively.

In some examples, one or more thermal bodies 155 can be coupled to electronic components 110 and/or interposer 140. Some examples can include disposing thermal bodies 155 on proximal side 143 of interposer 140, for example within inner conductive region 149. In some examples, thermal bodies 155 can be disposed on inner terminals 148 of inner conductive region 149. In some examples, thermal bodies 155 can be disposed on inner conductive region 149 and vertically aligned with distal side 111 of electronic component 110 and/or with metallization layer 118.

According to various examples, thermal bodies 155 can comprise a thermally conductive material such as solder, solder paste, metal, metal alloys, or the like. In some examples, thermal bodies 155 can be applied in various forms such as wire, paste, preforms, or the like. In some examples, thermal bodies 155 can be provided by dispensing, ball drop, screen printing, electrolytic plating, coupling a pre-formed structure on inner terminals 148 and/or on distal side 111 of electronic component 110 and/or on metallization layer 118. In some examples, thermal bodies 155 can be applied as a solder paste which can then be reflowed to provide a plurality of solder structures such as individual or otherwise separate solder bumps, pillars, columns, or the like.

FIG. 2C shows a cross-sectional view of electronic device 100 at a later stage of manufacture. In FIG. 2C, interposer 140 is coupled to substrate 130 through one or more vertical interconnects 150. In some examples, interposer 140 with vertical interconnects 150 coupled to proximal side 143 can be placed on distal side 133 of substrate 130. In some examples, interposer 140 with or without vertical interconnects 150 coupled to proximal side 143 can be placed on distal side 133 of substrate 130 having vertical interconnects 150 coupled to proximal side 135 of substrate 130. Vertical interconnects 150 can be in contact with and coupled to inner terminals 138 of substrate 130, inner terminals 148 of interposer 140, and/or other vertical interconnect segments 150a, 150b through a reflow, thermal compression bonding, laser assisted bonding, or any other suitable coupling process.

In some examples, vertical interconnects 150 can be coupled to inner terminals 148 of interposer 140 and/or inner terminals 138 of substrate 130 through a thermocompression or reflow process to couple core structure 151 to inner terminals 148 and inner terminals 138 through fusible material 152. An upper side of vertical interconnects 150 can be in contact with and coupled to inner terminals 148 of interposer 140 and a lower side of vertical interconnects 150 can be in contact with and coupled to inner terminals 138 of substrate 130. Vertical interconnects 150 can electrically couple conductive structure 144 of interposer 140 to conductive structure 134 of substrate 130.

In some examples, thermal bodies 155 can be coupled between electronic component 110 and interposer 140. Thermal bodies 155 can be coupled to distal side 111 of electronic component 110, for example to metallization layer 118. In some examples, thermal bodies 155 can be coupled to electronic component 110 and/or metallization layer 118 using, for example, a reflow, thermocompression, or other suitable process to reflow, cure, or otherwise set thermal bodies 155. Thermal bodies 155 can extend between and vertically fill a space between electronic component 110 and interposer 140, for example between metallization layer 118 and inner terminals 148 of inner conductive region 149. In some examples, thermal bodies 155 can have a thickness of 0.1 micrometers (μm) to 1000 μm, for example from 10 μm to 500 μm, for example from approximately 50 μm to approximately 200 μm.

FIG. 2D shows a cross-sectional view of electronic device 100 at a later stage of manufacture. In the example shown in FIG. 2D, encapsulant 160 is provided between substrate 130 and interposer 140, around vertical interconnects 150, around electronic component 110, and between and/or around thermal bodies 155. In some cases, the support carrier used for disposing interposer 140 over substrate 130 (FIG. 2C) can be removed after providing encapsulant 160.

Encapsulant 160 can fill the volume between distal side 133 of substrate 130 and proximal side 143 of interposer 140. Encapsulant 160 can surround electronic components 110, thermal bodies 155, and vertical interconnects 150. Encapsulant 160 can be located between distal side 111 of electronic component 110 and proximal side 143 of interposer 140. In some examples, encapsulant 160 can contact vertical interconnects 150, the side walls of thermal bodies 155, and the side walls of electronic component 110. Encapsulant 160 can be located between proximal side 112 of electronic component 110 and distal side 133 of substrate 130. For example, encapsulant 160 can be a molded underfill (MUF) and can contact connectors 114. In some examples, underfill 116, distinct from encapsulant 160, can be located between proximal side 112 of electronic component 110 and distal side 133 of substrate 130, and encapsulant 160 can extend to and can contact underfill 116.

Encapsulant 160 can comprise or be referred to as a package body, an encapsulating structure, an insulator, a mold, an epoxy molding compound (EMC), a resin, a filler-reinforced polymer, a B-stage compressed film, gel, etc. Encapsulant 160 can be provided by transfer molding, compression molding, liquid encapsulant molding, vacuum lamination, paste printing, film assisted molding, or any other suitable process.

The thickness of encapsulant 160 between substrate 130 and interposer 140 can be similar to or the same as the height of vertical interconnects 150. In some examples, the thickness of encapsulant 160 can range from about 50 μm to about 420 μm. Encapsulant 160 can protect electronic component 110, vertical interconnects 150, and thermal bodies 155, thereby improving the reliability. Encapsulant 160 can be provided to cover electronic components 110 and can improve the efficiency of heat dissipation from electronic components 110, compared to an electronic device in which encapsulant 160 is not provided.

FIG. 2E shows a cross-sectional view of electronic device 100 at a later stage of manufacture. In the example shown in FIG. 2E, external interconnects 170 are provided and singulation is performed.

External interconnects 170 can comprise or be referred to as solder, solder balls, bumps, tin bumps, tin-lead (SnPb) bumps, lead-free bumps, pads, pillars, etc. External interconnects 170 can be coupled to outer terminals 136 of substrate 130. External interconnects 170 can serve to couple electronic device 100 to an external device. In some examples, external interconnects 170 can form a ball grid array (BGA).

In some examples, external interconnects 170 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 170 can be provided by forming a conductive material including solder on outer terminals 136 of substrate 130 through a ball drop method, and then a reflow process. External interconnects 170 can comprise or be referred to as conductive balls such as solder balls, conductive pillars such as copper pillars, conductive posts, bumps, or solder capped copper pillars. In some examples, the height of external interconnects 170 can range from about 25 μm to about 100 μm. In some examples, external interconnects 170 can be referred to as external input/output terminals of electronic device 100. In some examples, electronic device 100 can be implemented in a land grid array (LGA) configuration and outer terminals 136 of substrate 130 can serve as external input/output terminals. In some such examples, electronic device 100 can be devoid of external interconnects 170.

In the example shown in FIG. 2E, singulation can also be performed. In some examples, a singulation process can be performed after providing external interconnects 170. Other examples can include performing a singulation prior to providing external interconnects 170. In accordance with various examples, singulation can be performed by cutting through saw streets, for example indicated by lines 180, disposed around a perimeter of electronic devices 100, thereby separating individual electronic devices 100 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through substrate 130, interposer 140, and/or encapsulant 160. In some examples, after singulation, encapsulant 160 can be coplanar with the lateral sides of interposer 140 and/or the lateral sides of substrate 130. In some examples, after singulation, vertical interconnects 150 can be located in an edge region of electronic device 100, for example at edge regions of substrate 130 and/or interposer 140. For example, vertical interconnects 150 can be between electronic components 110 and the lateral sides of substrate 130 and interposer 140.

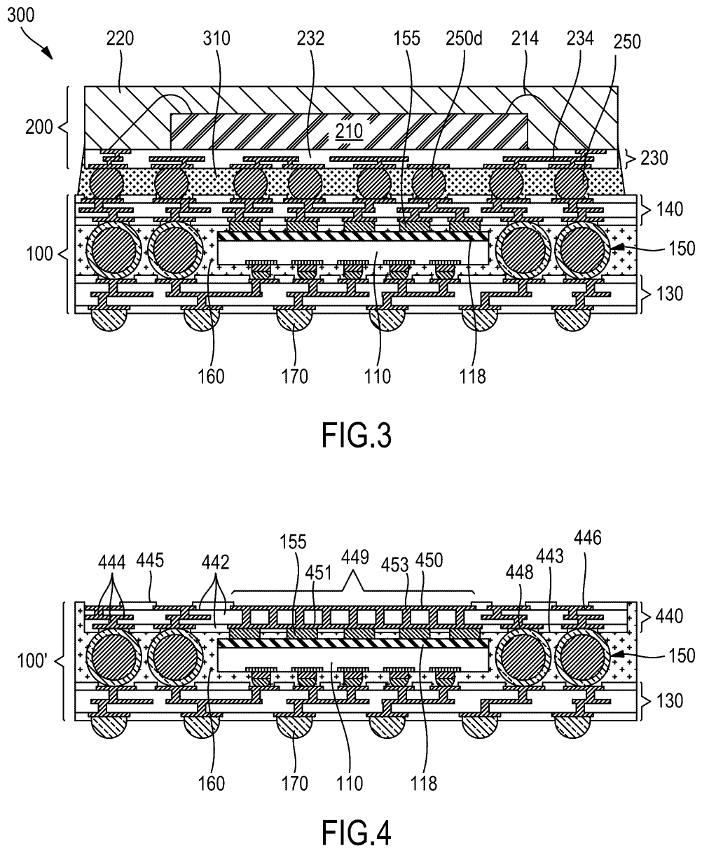

FIG. 3 shows a cross-sectional view of a stacked electronic device 300 at a later stage of manufacture. In the example shown in FIG. 3, electronic device 200 can be coupled to electronic device 100 through interposer 140 to create electronic device 300. Electronic device 300 can comprise or be referred to as a stacked electronic device.

In some examples, electronic device 200 can comprise electronic component 210, encapsulant 220, and substrate 230. In some examples, electronic device 200 can comprise a memory module, a processing module, a control module, other packaged electronic component(s), or the like. Electronic device 200 can be partially or fully assembled prior to placing on electronic device 100.

In according with various examples, substrate 230 can comprise dielectric structure 232 and conductive structure 234. In some examples, dielectric structure 232 can comprise or be referred to as one or more stacked dielectric layers. For instance, the one or more dielectric layers can comprise one or more core layers, polymer layers, pre-preg layers, solder mask layers, or the like stacked on each other. One or more layers or elements of conductive structure 234 can be interleaved with elements or layers of dielectric structure 232. In some examples, dielectric structure 232 can comprise FR4, BT, PI, BCB, PBO, ABF, resin, mold compound, ceramic, glass, silicon, or copper clad laminate. Dielectric structure 232 can have any suitable thickness. Dielectric structure 142 can maintain the shape of interposer 140 and can structurally support conductive structure 144.

Conductive structure 234 can comprise or be referred to as one or more conductive layers defining signal distribution elements, traces, vias, pads, conductive patterns, conductive paths, wiring patterns, circuit patterns, or UBM. In some examples, conductive structure 234 can comprise one or more layers of Cu, Al, Sn, Ti, TiW, Au, Ag, Ni, Pd, combinations or alloys thereof, or the like. The layers and elements of conductive structure 234 can be provided as described above with respect to the layers and elements of conductive structure 134. Conductive structure 234 can have any suitable thickness. Conductive structure 234 can provide electrical signal paths, for example vertical paths or horizontal paths, through dielectric structure 232. Conductive structure 234 can, for example, couple external connections to one or more electronic components 210. In some examples, conductive structure 234 can provide electrical signal paths between one or more electronic components 210. In some examples, conductive structure 234 can provide electrical signal paths to other features of electronic device 300, such as vertical interconnects 250, interposer 140, vertical interconnects 150, conductive structure 134 of substrate 130, electronic component 110, or the like.

Conductive structure 234 can be exposed at a proximal side of substrate 230 and/or at a distal side of substrate 230 opposite the proximal side. In some examples, elements, features, materials, or manufacturing methods of substrate 230 can be similar to or the same as those of substrate 130. In some examples, substrate 230 can comprise or be referred to as an interposer. Substrate 230 can comprise a core or be coreless. In some examples, substrate 230 can comprise or be referred to as a pre-formed or laminate substrate, as previously described. In some examples, substrate 230 can comprise or be referred to as an RDL substrate, as previously described.

In accordance with various examples, electronic component 210 can comprise or be referred to as a die, chip, semiconductor package (e.g., multiple interconnected and/or stacked die), passive component, antenna patch, power device, or the like. In some examples, electronic component 210 can comprise a digital signal processor (DSP), network processor, power management unit, audio processor, radio-frequency (RF) circuit, wireless baseband processor, system-on-chip (SoC) processor, sensor, application-specific integrated circuit (ASIC), or the like. In some examples, electronic component 210 can be configured to perform calculation and control processing, store data, or remove noise from electrical signals. In some examples, one or more electronic component(s) 210 can comprise a memory die or memory package.

In accordance with various embodiments, one or more electronic components 210 can be coupled to conductive structure 234 of substrate 230. In some examples, electronic component 210 can be coupled to conductive structure 234 at distal side of substrate 230. For example, one or more of electronic components 210 can be coupled to conductive structure 234 as described above with respect to electronic component 110. In some examples, one or more electronic components 210 can be coupled to conductive structure 234 through connectors 214 such as wire bond or other coupling technology.

In accordance with various embodiments, encapsulant 220 can be disposed over electronic component 210 and substrate 230. In some examples, elements, features, materials, or manufacturing methods of encapsulant 220 can be similar to or the same as those of encapsulant 160. For example, encapsulant 220 can be provided around electronic component 210 and connectors 214. In some examples, an underfill, distinct from encapsulant 220, can be located between a proximal side of electronic component 210 and a distal side of substrate 230, and encapsulant 220 can extend to and can contact the underfill.

In some examples, encapsulant 220 can comprise or be referred to as a package body, an encapsulating structure, an insulator, a mold, an epoxy molding compound (EMC), a resin, a filler-reinforced polymer, a B-stage compressed film, gel, etc. Encapsulant 220 can be provided by transfer molding, compression molding, liquid encapsulant molding, vacuum lamination, paste printing, film assisted molding, or any other suitable process.

In accordance with various embodiments, vertical interconnects 250, vertical interconnects 250d, and electronic device 200 can be provided over interposer 140. In some examples, vertical interconnects 250 and 250d can be coupled to substrate 230 and then electronic device 200, having vertical interconnects 250 and 250d coupled thereto, is disposed over interposer 140. In some examples, vertical interconnects 250 and 250d can be coupled to interposer 140, and then substrate 230 of electronic device 200 can be disposed over interposer 140 and vertical interconnects 250 and 250d.

In some examples, elements, features, materials, or manufacturing methods of vertical interconnects 250 and/or 250d can be similar to or the same as those of vertical interconnects 150 and/or external interconnects 170. In some examples, vertical interconnects 250 and/or 250d can comprise or be referred to as balls, bumps, solder balls, lead-free bumps, pads, tin-lead (SnPb) bumps, plated pillars, pre-formed pins, copper column cubes (CCCs) (e.g., vertical interconnects 150 can include a plurality of encapsulated conductive (e.g., Cu) columns), solder coated metallic core balls (e.g., solder coated Cu core balls), solder coated metallic core pins (e.g., solder coated Cu core pins), vertical wires, or the like. Vertical interconnects 250 and/or 250d can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. In some examples, vertical interconnects 250 and/or 250d can be provided by ball drop, screen printing, electrolytic plating, or coupling a pre-formed structure on outer terminals 146 of interposer 140 and/or conductive structure 234 on a proximal side of substrate 230. The vertical interconnects 250 and/or 250d can be configured to minimize or otherwise maintain a distance between interposer 140 and substrate 230, for example to aid thermal transfer from electronic device 100 to electronic device 200. Vertical interconnects 250 and/or 250d can be in contact with and coupled to outer terminals 146 of interposer 140 and conductive structure 234 of substrate 230 through a reflow, thermal compression (thermocompression) bonding, laser assisted bonding, or any other suitable coupling process.

In some examples, vertical interconnects 250d can be coupled with conductive structure 144 of inner conductive region 149. Vertical interconnects 250d can provide thermal coupling between inner conductive region 149 of interposer 140 and substrate 230 of electronic device 200. In some examples, vertical interconnects 250d can be coupled between outer terminals 146 of inner conductive region 149 and conductive structure 234 of electronic device 200. In some such examples, electronic device 200 may be electrically isolated from conductive structure 144 of inner conductive region 149, and vertical interconnects 250d can be referred to or comprise dummy connections, dummy bumps, thermal interconnect structures, or the like. For example, vertical interconnects 250d may couple conductive structure 144 of interposer 140 to substrate 230 and/or to a region of conductive structure 234 having no electrical connection to electronic component 210. In some examples, conductive structure 144 of inner conductive region 149 can provide electrical signal paths (e.g., vertical paths and horizontal paths) for electronic device 200, for example through vertical interconnects 250d.

In some examples, vertical interconnects 250 can be coupled with conductive structure 144 of interposer 140 external to inner conductive region 149. Vertical interconnects 250 can be coupled between outer terminals 146 surrounding inner conductive region 149 and conductive structure 234 of electronic device 200. In some examples, conductive structure 144 of interposer 140 external to inner conductive region 149 can provide electrical signal paths for electronic device 200, for example through vertical interconnects 250.

In accordance with various embodiments, underfill 310 can be disposed between electronic device 200 and electronic device 100, before or after placement and/or coupling of electronic device 200 on interposer 140. Underfill 310 can include a liquid molding compound (LMC), a capillary underfill (CUF), a molded underfill (MUF), a nonconductive paste (NCP), or the like. In some examples, underfill 310 can be applied by dispensing or printing. In some examples, underfill 310 can couple or otherwise be in contact with distal side 145 of interposer 140 in inner conductive region 149 and proximal side of substrate 230. In some examples, underfill 310 can partially or completely fill the space between electronic device 100 and electronic device 200, for example surrounding and protecting vertical interconnects 250 and 250d. In some embodiments, an air gap can be present between electronic device 100 and electronic device 200, for example through partial filling of the space between electronic device 100 and electronic device 200 with underfill 310 or excluding underfill 310 between electronic device 100 and electronic device 200.

In some examples, underfill 310 can provide a thermal pathway between interposer 140 and electronic device 200. For example, thermal energy generated by electronic component 110 can be more efficiently transferred from electronic component 110 through thermal bodies 155, through inner conductive region 149 of interposer 140, through underfill 310, through vertical interconnects 250d, and through electronic device 200 to an external environment, external heat sink, or the like. The thermal pathway can provide improved performance of electronic device 100, electronic device 200, and/or electronic device 300 by reducing the thermal resistance between electronic component 110 and electronic device 200. In some examples, underfill 310 can partially or completely cover distal side 145 of interposer 140. In some examples, underfill 310 can cover an area on distal side 145 of interposer 140 matching an area of inner conductive region 149. In some examples, the thickness of underfill 310 can range from approximately 1 μm to 250 μm.

In some examples, underfill 310 can comprise a thermal interface material. A thermal interface material can include a thermally conductive material. In some examples, a thermal interface material can provide adhesion between interposer 140 and electronic device 200. In some examples, a thermal interface material can comprise or be referred to as a metallic thermal interface material (TIM). For example, a thermal interface material can comprise a thermally conductive material such as solder, solder paste, or metal alloy materials such as gallium, gallium alloys (e.g., alloys with indium, tin, and zinc), silver alloys, tin-silver, indium, or indium alloys. In some examples, a thermal interface material can comprise, for example, a non-metallic interface or non-metallic material such as an organic compound, an inorganic compound, a polymer, or a thermally conductive filler, or other thermal interface material, and the scope of the disclosed subject matter is not limited in this respect.

FIG. 4 shows a cross-sectional view of an example electronic device 100′. In the example shown in FIG. 4, electronic device 100′ can comprise the same or similar features and elements as electronic device 100, for example electronic component 110, metallization layer 118, substrate 130, interposer 440, vertical interconnects 150, thermal bodies 155, encapsulant 160, and external interconnects 170. In some examples, electronic device 100′ can include interposer 440 singulated prior to placement on vertical interconnects 150 and coupling to substrate 130.

Interposer 440 can comprise the same or similar features and elements as interposer 140. For example, interposer 440 can include conductive structure 444, dielectric structure 442, proximal side 443, distal side 445, outer terminals 446, inner terminals 448, and inner conductive region 449. In some examples, elements, features, materials, or manufacturing methods of conductive structure 444, dielectric structure 442, proximal side 443, distal side 445, outer terminals 446, inner terminals 448, and/or inner conductive region 449 of interposer 440 can be the same or similar as those of conductive structure 144, dielectric structure 142, proximal side 143, distal side 145, outer terminals 146, inner terminals 148, and/or inner conductive region 149 of interposer 140, respectively.

In some examples, inner conductive region 449 can include proximal plate 451 thermally coupled to distal plate 450, for example through conductive vias 453. Distal plate 450 and proximal plate 451 can comprise any suitable thermally conductive material, for example a metal such as Cu, Al, Sn, Ti, TiW, Au, Ag, Ni, Pd, combinations or alloys thereof, or the like, and each may be referred to as a thermal plate. In some examples, distal plate 450 and/or proximal plate 451 can comprise a metallization layer, for example provided as described above with respect to metallization layer 118. In some examples, proximal plate 451 can comprise the same conductive structure 444 layer as inner terminals 448, and distal plate 450 can comprise the same conductive structure 444 layer as outer terminals 446. Proximal plate 451 and/or distal plate 450 can be partially or fully exposed from dielectric structure 442.

Encapsulant 160 can extend to the exterior edges of electronic device 100′, and can be coplanar with one or more lateral sides of substrate 130. Interposer 440 can comprise a plurality of outer sidewalls facing the exterior of the interposer 440 and the exterior of electronic device 100′. Interposer 440 can have lateral dimensions smaller than substrate 130 in one or more directions. Outer sidewalls of interposer 440 can be recessed from the lateral sides of substrate 130 and exterior sides of encapsulant 160. In some examples, encapsulant 160 can be disposed between outer sidewalls of interposer 140 and edges of electronic device 100.

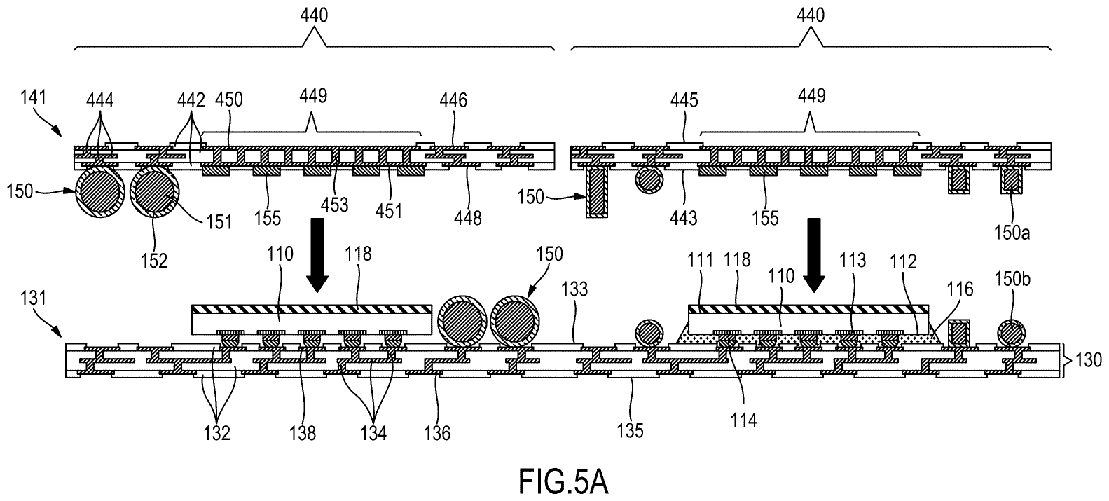

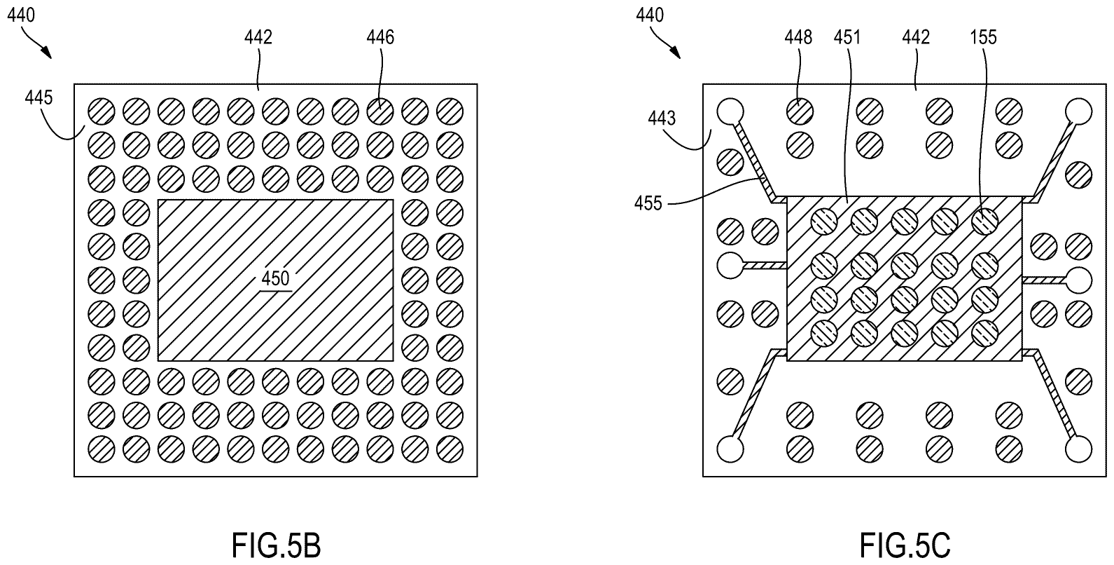

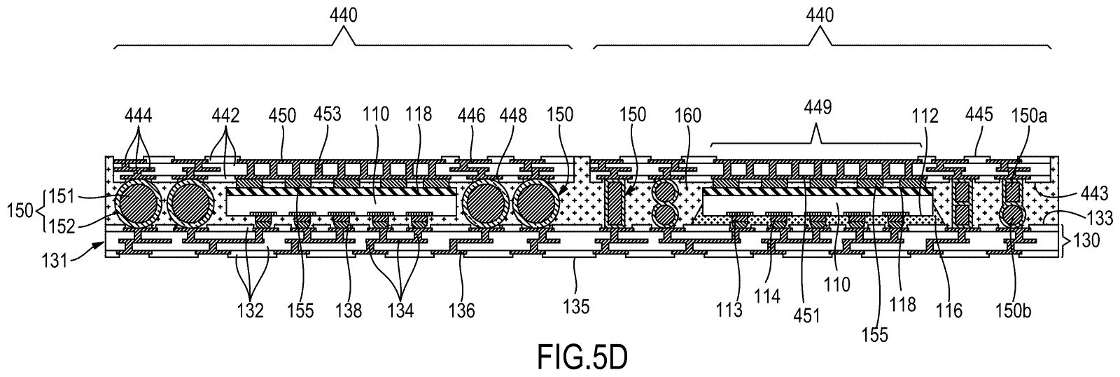

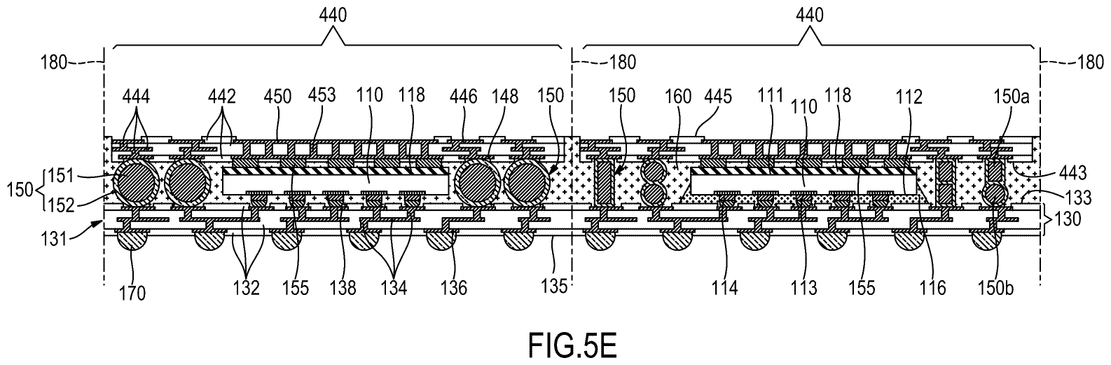

FIGS. 5A to 5E show an example method for manufacturing an electronic device, such as electronic device 100′ in FIG. 4, using cross-sectional and top-down views. FIGS. 5A, 5C, and 5D illustrate cross-sectional views of an alternate example method of manufacturing an electronic device from those illustrated in FIGS. 2A to 2F. FIGS. 5B and 5C illustrate a top-down view of an example arrangement of structures of interposer 440. For example, FIGS. 2A to 2F illustrate providing substrate 130 and interposer 140 as strips 131, 141 followed by coupling substrate 130 to interposer 140 through vertical interconnects 150 and then singulating individual electronic devices 100. FIGS. 5A to 5E illustrate first providing separate interposers 440 for each electronic device 100′. In some examples, interposer 440 can be singulated from strip 141 or the like prior to coupling with substrate 130. It will be understood that either ordering of steps, or other orderings, can be used to manufacture electronic device 100 (FIG. 1) and electronic device 100′ (FIG. 4).

FIG. 5A shows a cross-sectional view of electronic device 100′ at an early stage of manufacture. In the example shown in FIG. 5A, substrate 130 is provided, electronic components 110 are provided over substrate 130, metallization layer 118 is provided over electronic component 110, vertical interconnects 150, 150a, and/or 150b are provided on substrate 130 and/or interposer 440, thermal bodies 155 are provided on interposer 440 and/or electronic component 110, and interposer 440 is provided over substrate 130. In some examples, elements, features, materials, or manufacturing methods shown and described with respect to FIG. 5A, for example electronic component 110, metallization layer 118, underfill 116, substrate 130, interposer 440, inner conductive region 449, thermal bodies 155, and vertical interconnects 150, 150a, and 150b, can be similar to or the same as those shown and described with respect to FIGS. 2A to 2B.

For example, substrate 130 can be provided as part of a strip 131 of substrates 130. In some examples, substrate 130 can be a pre-formed substrate, an RDL substrate, or the like. Substrate 130 can comprise dielectric structure 132 and conductive structure 134, and electronic component 110 can be coupled to conductive structure 134 of substrate 130. In some examples, underfill 116 can be disposed between electronic component 110 and substrate 130. Some examples can include disposing metallization layer 118 on distal side 111 of electronic component 110. Some examples can include disposing proximal interconnect segments 150b to inner terminals 138 of substrate 130.

In some examples, inner conductive region 449 can be provided with proximal plate 451 and/or distal plate 450. Proximal plate 451 and distal plate 450 can comprise thermally conductive material, for example as described above. In some examples, distal plate 450 can be thermally coupled with proximal plate 451 through other conductive structures, for example through conductive structure 444, conductive vias 453, or the like.

In some examples, distal plate 450 and/or proximal plate 451 can comprise a metallization layer, metal body, or metal lid disposed on distal side 445 and/or proximal side 443 of interposer 440, respectively. In some examples, distal plate 450 and/or proximal plate 451 can comprise a metallization disposed on interposer 440, for example provided as described above with respect to metallization layer 118.

In some examples, proximal plate 451 and distal plate 450 can each comprise a layer of conductive structure 444 and can be provided by exposing conductive structure 444 from dielectric structure 442. For example, proximal plate 451 can comprise the same layer of conductive structure 444 as inner terminals 448, and distal plate 450 can comprise the same layer of conductive structure 444 as outer terminals 446. Distal plate 450 and proximal plate 451 can comprise continuous, unbroken regions of conductive structure 444. In some examples, distal plate 450 and proximal plate 451 can comprise portions of conductive structure 444 exposed through a continuous opening in dielectric structure 442. For example, distal plate 450 and proximal plate 451 can be exposed from dielectric structure 442 through a large central opening, through an opening spanning all of or substantially all of inner conductive region 449, or the like.

In some examples, distal plate 450 and proximal plate 451 can comprise portions of conductive structure 444 exposed through individual, discrete openings in dielectric structure 442. For example, distal plate 450 and proximal plate 451 can be exposed from dielectric structure 442 through openings similar to or the same as used for exposing outer terminals 446 and inner terminals 448 from dielectric structure 442. The respective openings in dielectric structure 442 can be created through etching, laser ablation, or other suitable process for removing dielectric structure 442. In some examples, thermal bodies 155 can then be disposed on or otherwise coupled to proximal plate 451, for example by dispensing, ball drop, screen printing, electrolytic plating, coupling a pre-formed structure on exposed portions of proximal plate 451, or the like.

Interposers 440 can be provided as one or more separate individual substrates. In some examples, vertical interconnects 150, 150a, thermal bodies 155, and separate interposers 440 can be provided over substrate 130. Interposer 440 can be singulated prior to providing over substrate 130. Interposers 440 can be coupled to a carrier and then provided over substrate 130. In some examples, pick-and-place equipment can pick up interposer(s) 440 and align interposer 440, vertical interconnects 150, and substrate 130.

In some examples, vertical interconnects 150 and/or 150a and thermal bodies 155 can be coupled to interposers 440. Interposers 440, having vertical interconnects 150, 150a and thermal bodies 155 coupled thereto, can then be disposed over substrate 130. In some examples, vertical interconnects 150 can be coupled to substrate 130, and then interposers 440 can be disposed over vertical interconnects 150 and substrate 130. In some examples, vertical interconnects 150 can comprise multiple interconnect segments 150a, 150b. In some such examples, proximal interconnect segment 150b can be coupled to substrate 130 and distal interconnect segment 150a can be coupled to interposers 440. Interposers 440 can then be disposed over substrate 130 such that the proximal interconnect segments 150b can couple with the distal interconnect segments 150a. In some examples, thermal bodies 155 can be coupled to distal side 111 of electronic component 110, for example to metallization layer 118, and then interposer 440 can be disposed over substrate 130.

FIG. 5B shows a top-down view of distal side 445 of an example interposer 440, and FIG. 5C shows a top-down view of proximal side 443 of the example interposer 440. In some examples, interposer 440 of FIGS. 5B and 5C can be provided as part of the manufacturing process described with respect to FIG. 5A.

Interposer 440 can include distal plate 450 exposed from surrounding dielectric structure 442 on distal side 445 of interposer 440. Outer terminals 446 can be provided surrounding distal plate 450, for example to provide a coupling with an electronic component to be placed over distal side 445 of interposer 440 at a later step in manufacturing. Interposer 440 can include proximal plate 451 exposed from surrounding dielectric structure 442 on proximal side 443 of interposer 440. Inner terminals 448 can be provided surrounding proximal plate 451, for example to provide coupling with vertical interconnects 150, 150a, 150b. One or more thermal bodies 155 can be provided on proximal plate 451.

In some examples, interposer 440 can comprise one or more lateral dissipation structures 455. Lateral dissipation structures 455 can facilitate removal of thermal energy from electronic component 110, inner conductive region 449, and the like. Lateral dissipation structures 455 can comprise a thermally conductive material, for example as described above, and can provide a thermal pathway extending laterally from inner conductive region 449 of interposer 440. In some examples, lateral dissipation structures 455 can include continuous pathways of the same material as proximal plate 451 and/or distal plate 450 that extend laterally from proximal plate 451 and/or distal plate 450 to a region outside the footprint of electronic component 110. Lateral dissipation structures 455 can be coupled to proximal plate 451 and/or distal plate 450. In some examples, lateral dissipation structures 455 can extend to or substantially to an exterior side of interposer 440. In some examples, lateral dissipation structures 455 can include a layer of conductive structure 444, for example the same layer of conductive structure 444 from which inner terminals 448 are formed. In some examples, lateral dissipation structures 455 can be partially or completely exposed from dielectric structure 442, or can be encapsulated within dielectric structure 442. Lateral dissipation structures 455 can extend to active (e.g., electrically coupled) or inactive (e.g., dummy) inner terminals 448.

FIG. 5D shows a cross-sectional view of electronic device 100′ at a later stage of manufacture. In the example shown in FIG. 5D, interposer 440 is coupled to substrate 130 through one or more vertical interconnects 150, 150a, and/or 15b, and encapsulant 160 is provided between substrate 130 and interposer 140, around vertical interconnects 150, around electronic component 110, and between and/or around thermal bodies 155. In some examples, elements, features, materials, or manufacturing methods shown and described with respect to FIG. 5D, for example encapsulant 160, thermal bodies 155, etc., can be similar to or the same as those shown and described with respect to FIGS. 2C to 2D.

For example, interposer 440 can be coupled with substrate 130. Vertical interconnects 150 can be in contact with and coupled to inner terminals 138 of substrate 130, inner terminals 148 of interposer 440, and/or other vertical interconnect segments 150a, 150b through a reflow, thermal compression bonding, laser assisted bonding, or any other suitable coupling process. In some examples, distal plate 450 can be exposed at or otherwise provided on distal side 445 of interposer 440 after coupling interposer 440 to substrate 130.

In some examples, encapsulant 160 can fill the volume between distal side 133 of substrate 130 and proximal side 443 of interposer 440. Encapsulant 160 can surround electronic components 110, thermal bodies 155, and vertical interconnects 150, 150a, 150b. In some examples, interposer 440 can have lateral dimensions smaller than lateral dimensions of substrates 130 after substrates are subsequently singulated. For example, outer sidewalls of interposer 440 can be recessed from the to-be-exposed lateral sides of substrate 130 and exterior sides of encapsulant 160. In some examples, encapsulant 160 can be disposed between outer sidewalls of adjacent interposers 440.

In some examples, encapsulant 160 can be a molded underfill (MUF) and can contact connectors 114. In some examples, underfill 116, distinct from encapsulant 160, can be located between proximal side 112 of electronic component 110 and distal side 133 of substrate 130, and encapsulant 160 can extend to and can contact underfill 116. In some examples, encapsulant 160 can comprise or be referred to as a package body, an encapsulating structure, an insulator, a mold, an epoxy molding compound (EMC), a resin, a filler-reinforced polymer, a B-stage compressed film, gel, etc. Encapsulant 160 can be provided by transfer molding, compression molding, liquid encapsulant molding, vacuum lamination, paste printing, film assisted molding, or any other suitable process.

FIG. 5E shows a cross-sectional view of electronic device 100′ at a later stage of manufacture. In the example shown in FIG. 5E, external interconnects 170 are provided and singulation is performed. In some examples, elements, features, materials, or manufacturing methods shown and described with respect to FIG. 5C, for example external interconnects 170, saw streets, singulation, etc., can be similar to or the same as those shown and described with respect to FIG. 2E.

For example, external interconnects 170 can be coupled to outer terminals 136 of substrate 130 and can comprise or be referred to as solder, solder balls, bumps, tin bumps, tin-lead (SnPb) bumps, lead-free bumps, pads, pillars, etc. In some examples, external interconnects 170 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. In some examples, electronic device 100′ can comprise a BGA or an LGA configuration.

In the example shown in FIG. 5E, singulation can also be performed. In some examples, a singulation process can be performed after providing external interconnects 170. Other examples can include performing a singulation prior to providing external interconnects 170. In some examples, singulation can be performed by cutting through saw streets, for example indicated by lines 180, disposed around a perimeter of electronic devices 100′, thereby separating individual electronic devices 100′ from one another. Singulation can include cutting through substrate 130 and/or encapsulant 160. In some examples, interposer 440 has sufficiently smaller dimensions than substrate 130 such that interposer 440 is not cut during singulation. Other examples can include cutting through interposer 440 during singulation.

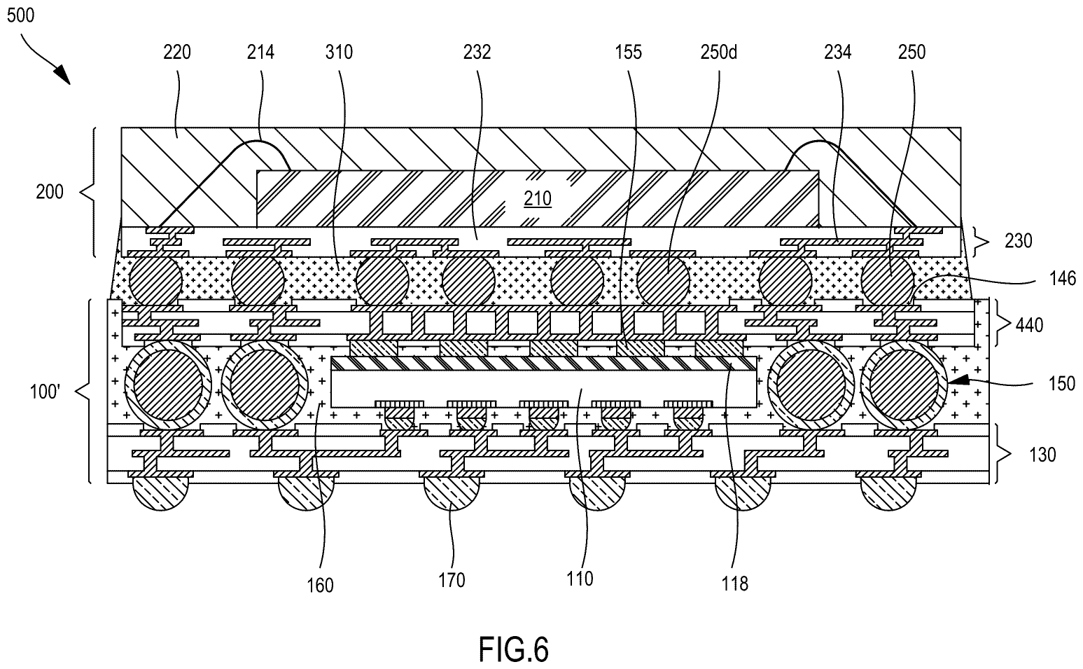

FIG. 6 shows a cross-sectional view of a stacked electronic device 500 at a later stage of manufacture. In the example shown in FIG. 6, electronic device 200 can be coupled to electronic device 100′ through interposer 440 to create electronic device 500. Electronic device 500 can comprise or be referred to as a stacked electronic device. In some examples, the elements, features, materials, or manufacturing methods shown and described with respect to FIG. 6 can be similar to or the same as those shown and described with respect to FIG. 3.

In some examples, after the singulation of FIG. 5E, encapsulant 160 can be coplanar with the lateral sides of substrate 130. In some examples, outer sidewalls of interposer 440 can be recessed from lateral sides of substrate 130 and encapsulant 160 after singulation. For example, encapsulant 160 can be disposed between outer sidewalls of interposer 440 and edges of electronic device 100′. In some examples, after singulation, vertical interconnects 150 can be located in an edge region of electronic device 100′, for example at edge regions of substrate 130 and/or interposer 440. For example, vertical interconnects 150 can be between electronic components 110 and the lateral sides of substrate 130 and interposer 440.

In some examples, electronic device 200 can be coupled to electronic device 100′, for example as described with respect to coupling electronic device 200 to electronic device 100 in FIG. 3. For example, vertical interconnects 250, vertical interconnects 250d, and electronic device 200 can be provided over interposer 440. In some examples, vertical interconnects 250 and 250d can be coupled to substrate 230 and then electronic device 200, having vertical interconnects 250 and 250d coupled thereto, is disposed over interposer 440. In some examples, vertical interconnects 250 and 250d can be coupled to interposer 440, and then substrate 230 of electronic device 200 can be disposed over interposer 440 and vertical interconnects 250 and 250d.

The vertical interconnects 250 and/or 250d can be arranged to aid thermal transfer from electronic device 100′ to electronic device 200. Vertical interconnects 250 can be in contact with and coupled to outer terminals 446 of interposer 440 and conductive structure 234 of substrate 230 through a reflow, thermal compression bonding, laser assisted bonding, or any other suitable coupling process. Vertical interconnects 250d can be in contact with and coupled to distal plate 450 of interposer 440 and substrate 230 through a reflow, thermal compression bonding, laser assisted bonding, or any other suitable coupling process. In some examples, vertical interconnects 250d can be coupled to conductive structure 234 of substrate 230 and inner conductive region 449. In some examples, portions of conductive structure 234 of substrate 230 that are coupled to inner conductive region 449 can be electrically isolated from portions of conductive structure 234 of substrate 230 coupled to vertical interconnects 250 surrounding inner conductive region 449.

In accordance with various embodiments, underfill 310 can be disposed between electronic device 200 and electronic device 100′, before or after placement and/or coupling of electronic device 200 on interposer 440. Underfill 310 can include a liquid molding compound (LMC), a capillary underfill (CUF), a molded underfill (MUF), a nonconductive paste (NCP), or the like. In some examples, underfill 310 can comprise a thermal interface material. In some examples, underfill 310 can couple or otherwise be in contact with distal side 445 of interposer 440 and a proximal side of substrate 230. In some examples, underfill 310 can partially or completely cover distal side 445 of interposer 440. In some examples, underfill 310 can cover an area on distal side 445 of interposer 440 matching an area of inner conductive region 449. In some examples, the thickness of underfill 310 can range from approximately 1 μm to 250 μm.

In some examples, underfill 310 and/or vertical interconnects 250d can provide a thermal pathway between interposer 440 and electronic device 200. For example, thermal energy generated by electronic component 110 can be more efficiently transferred from electronic component 110 through thermal bodies 155, through proximal plate 451, conductive vias 453, and distal plate 450 of interposer 440, through lateral dissipation structures 455, through underfill 310, through vertical interconnects 250d and/or vertical interconnects 250, and through electronic device 200 to an external environment, external heat sink, or the like. The thermal pathway can provide improved performance of electronic device 100′, electronic device 200, and/or electronic device 500 by reducing the thermal resistance between electronic component 110 and electronic device 200.

Electronic devices and associated manufacturing techniques can provide improved thermal performance. Exemplary electronic devices can include a substrate, an electronic component with a proximal side of the electronic component coupled to the substrate, and metallic core balls or other interconnects disposed around lateral sides of the electronic component and coupled to the substrate. An interposer can be coupled over the electronic component and to the interconnects. The interposer can include an inner conductive region disposed over the electronic component. The inner conductive region can be configured as a thermal pathway. Thermal bodies can be coupled between the inner conductive region and the electronic component. A mold material can be disposed between and/or around the thermal bodies, around the interconnects, and around the electronic component. A second electronic component can be coupled to a distal side of the interposer. The second electronic component can be electrically coupled to the interposer, for example in a region surrounding the inner conductive region. The second electronic component can be thermally coupled to the interposer, for example in the inner conductive region. In various examples, an underfill can be disposed between the interposer and the second electronic component.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate comprising a first side, a second side opposite the first side of the substrate, and a first conductive structure;
an electronic component coupled to the first conductive structure at the first side of the substrate, wherein the electronic component comprises a first side facing the first side of the substrate and a second side opposite the first side of the electronic component;
a plurality of vertical interconnects disposed around the electronic component, wherein the plurality of vertical interconnects are coupled to the first conductive structure at the first side of the substrate;
an interposer coupled to the plurality of vertical interconnects, wherein the interposer comprises a first side facing the first side of the substrate, a second side opposite the first side of the interposer, and a second conductive structure, and wherein the plurality of vertical interconnects are coupled to the second conductive structure at the first side of the interposer;
a thermal body coupled to the second side of the electronic component and to the first side of the interposer; and
an encapsulant disposed between the substrate and the interposer, around the thermal body, around the plurality of vertical interconnects, and around the electronic component.

2. The electronic device of claim 1, further comprising a first metallization layer on the second side of the electronic component, wherein the encapsulant is disposed between the metallization layer and the interposer.

3. The electronic device of claim 1, wherein the thermal body comprises a conductive paste.

4. The electronic device of claim 1, wherein the thermal body comprises a plurality of solder structures, and wherein the encapsulant is disposed between the plurality of solder structures.

5. The electronic device of claim 1, wherein the interposer further comprises an inner conductive region extending from the first side of the interposer to the second side of the interposer, wherein the plurality of vertical interconnects are disposed around the inner conductive region.

6. The electronic device of claim 5, wherein the inner conductive region comprises a thermal plate disposed on the first side of the interposer, and wherein the thermal body is coupled between the thermal plate and the second side of the electronic component.

7. The electronic device of claim 6, further comprising a lateral dissipation structure coupled with the thermal plate and extending laterally toward an exterior side of the interposer.

8. The electronic device of claim 5, wherein the inner conductive region comprises a second thermal plate disposed on the second side of the interposer.

9. The electronic device of claim 8, further comprising:
a second electronic component coupled to the second conductive structure at the second side of the interposer; and
an underfill disposed between the second thermal plate and the second electronic component.

10. The electronic device of claim 5, wherein the inner conductive region comprises a plurality of outer terminals of the second conductive structure exposed on the second side of the interposer.

11. The electronic device of claim 10, further comprising:
a second electronic component coupled to the second conductive structure at the second side of the interposer; and
a plurality of thermal interconnect structures coupled between the plurality of outer terminals and the second electronic component.

12. A method to manufacture an electronic device, comprising:
providing a substrate comprising a first side, a second side opposite the first side of the substrate, and a first conductive structure;
providing an electronic component coupled to the first conductive structure at the first side of the substrate, wherein the electronic component comprises a first side facing the first side of the substrate and a second side opposite the first side of the electronic component;
providing a plurality of vertical interconnects disposed around the electronic component, wherein the plurality of vertical interconnects are coupled to the first conductive structure at the first side of the substrate;
providing an interposer coupled to the plurality of vertical interconnects, wherein the interposer comprises a first side facing the first side of the substrate, a second side opposite the first side of the interposer, and a second conductive structure, and wherein the plurality of vertical interconnects are coupled to the second conductive structure at the first side of the interposer;
providing a thermal body coupled to the second side of the electronic component and to the first side of the interposer; and
providing an encapsulant disposed between the substrate and the interposer, around the thermal body, around the plurality of vertical interconnects, and around the electronic component.

13. The method of claim 12, wherein the thermal body comprises a conductive paste.

14. The method of claim 12, wherein the thermal body comprises a plurality of solder structures, and wherein the encapsulant is disposed between the plurality of solder structures.

15. The method of claim 12, wherein the interposer further comprises an inner conductive region extending from the first side of the interposer to the second side of the interposer, wherein the plurality of vertical interconnects are disposed around the inner conductive region.

16. The method of claim 15, wherein the inner conductive region comprises a first thermal plate disposed on the first side of the interposer and a second thermal plate disposed on the second side of the interposer, and wherein the thermal body is coupled between the first thermal plate and the second side of the electronic component.

17. An electronic device, comprising:
a substrate comprising a first side, a second side opposite the first side of the substrate, and a first conductive structure;
an electronic component coupled to the first conductive structure at the first side of the substrate, wherein the electronic component comprises a first side facing the first side of the substrate and a second side opposite the first side of the electronic component;
an interposer comprising a first side facing the first side of the substrate, a second side opposite the first side of the interposer, and a second conductive structure, and wherein the interposer comprises an inner conductive region extending from the first side of the interposer to the second side of the interposer;
a plurality of vertical interconnects disposed around the electronic component and around the inner conductive region, wherein the plurality of vertical interconnects are coupled to the first conductive structure at the first side of the substrate and are coupled to the second conductive structure at the first side of the interposer; and
an encapsulant disposed between the substrate and the interposer, around the plurality of vertical interconnects, and around the electronic component.

18. The electronic device of claim 17, further comprising:
a second electronic component disposed over the second side of the interposer;
a second plurality of vertical interconnects coupled to the second conductive structure and to the second electronic component outside of the inner conductive region; and
a plurality of thermal interconnect structures coupled between the second conductive structure and the second electronic component within the inner conductive region.

19. The electronic device of claim 18, wherein the second conductive structure within the inner conductive region is electrically isolated from the second conductive structure external to the inner conductive region.

20. The electronic device of claim 18, wherein the plurality of thermal interconnect structures are electrically conductive, and wherein the second conductive structure within the inner conductive region comprises one or more electrical pathways coupled to one or more of the plurality of thermal interconnect structures.
